(19) United States
(12) Patent Application Publication
(10) Pub. No.: US 2008/0308927 A1
(43) Pub. Date: Dec. 18, 2008

(54) Semiconductor device with heat sink plate

(75) Inventors: Haruto Nagata, Sakai-shi (JP); Masanori Minamio, Takatsuki-shi (JP); Hiroshi Horiki, Funai-gun (JP)

Correspondence Address: HAMRE, SCHUMANN, MUELLER & LARSON P.C., P.O. BOX 2902-0902, MINNEAPOLIS, MN, 55402, US

(73) Assignee: Matsushita Electric Industrial Co., Ltd., Kadoma-shi (JP)

(21) Appl. No.: 12/152,400

(22) Filed: May 14, 2008

Related U.S. Application Data
(62) Division of application No. 11/029,785, filed on Jan. 5, 2005.

(30) Foreign Application Priority Data
Jan. 9, 2004 (JP) 2004-004537

(51) Int. Cl. H01L 23/36

(52) U.S. Cl. 257/712; 257/E23.101

(57) ABSTRACT

A semiconductor chip is mounted on an upper surface of the heat sink plate that is provided with a plurality of heat releasing terminals on a lower surface of the heat releasing. A plurality of electric signal terminals are regularly disposed in a lattice-like manner around the heat sink plate. Lower end surfaces of the electric signal terminals and the heat releasing terminals are exposed from and sealed with a sealing resin. The heat sink plate is formed as an integrated body including a protruding portion that protrudes from a central portion of an upper surface and supports the semiconductor chip, a plurality of supporting portions that are positioned around a rear surface of the protruding portion so as to support the protruding portion and that are exposed at a rear surface of the sealing resin, the plurality of heat releasing terminals, and a thin-walled portion that is recessed from lower end surfaces of the supporting portions and the heat releasing terminals. Lower surfaces of the protruding portion and the thin-walled portion are covered with the sealing resin. The plurality of supporting portions are disposed so that they are continuous with the protruding portion and symmetrical to each other around the protruding portion. A degree of freedom is improved in board wiring below the heat sink plate in a land grid array type package.

This application is a division of U.S. Ser. No. 11/029,785, filed Jan. 5, 2005 which application is incorporated herein by reference.

### BACKGROUND OF THE INVENTION

1. Field of the Invention

The present invention relates to an improvement in the configuration of a heat sink plate on which a semiconductor chip is mounted, in a semiconductor device of the so-called land grid array type in which external terminals that are exposed at a lower surface of a sealing resin are regularly disposed in a lattice-like manner.

2. Description of the Related Art

Hereinafter, configurations of a semiconductor device according to a conventional example will be described with reference to the accompanying drawings. FIG. 6A to FIG. 6D are schematic views of an example of the configuration of the conventional semiconductor device described in JP 2000-124381A. FIG. 6A is a cross-sectional view and FIG. 6B is a bottom view. The cross-sectional view in FIG. 6A shows a cross-section taken along the line J-J in FIG. 6B. FIG. 6C is a bottom view of a heat sink plate constituting the semiconductor device, and FIG. 6D is a bottom view showing a lead frame constituting the semiconductor device.

As shown in FIG. 6A, a semiconductor chip 1 is mounted on a protruding portion 2a at the center of a heat sink plate 2 and bonded thereon by an adhesive 3 such as Ag paste. As shown in FIG. 6D, the heat sink plate 2 is formed in an integrated state with suspension leads 4 that extend from lands 4a at the four corners of the semiconductor device, and is firmly held by the suspension leads 4. Lands 4a on the suspension leads 4, which are exposed to the outside of the semiconductor device, also are formed in an integrated state. Electric signal terminals 5 are regularly disposed in a lattice-like manner on the outer side of the heat sink plate 2 that includes the protruding portion 2a for mounting the chip 1, and electrically connected to the semiconductor chip 1 via wires 6. The above elements are sealed with a sealing resin 7.

A supporting portion 2b that is formed around the protruding portion 2a of the heat sink plate 2 is a so-called full metal portion exposed to the outside of the semiconductor device, which means that its thickness is the original thickness of the lead frame, and serves to support the protruding portion 2a. The central recessed portion 2c on the lower surface of the protruding portion 2a has a configuration to which the sealing resin 7 does not flow, so that it is not sealed with resin and is exposed to the outside of the semiconductor device together with the supporting portion 2b. An outer peripheral portion 2d surrounding the supporting portion 2b is a thin-walled portion formed by half etching and is embedded in the sealing resin 7, however, a part thereof forms full metal heat releasing terminals 2e, which are exposed to the outside of the semiconductor device. The heat releasing terminals 2e have the shape, size, and arrangement similar to those of the electric signal terminals 5, and have no difference in the external appearance from the electric signal terminals 5 on the lower surface of the semiconductor device.

The above-described conventional semiconductor device has a problem in that after it is connected by solder to a circuit board, it is difficult to form wiring on the circuit board surface below the exposed heat sink plate 2. FIG. 7A and FIG. 7B show a state of the wring on the board surface. FIG. 7A is a cross-sectional view showing a state in which a semiconductor device 8 with the configuration shown in FIG. 6A to FIG. 6D is mounted on a circuit board 9, and FIG. 7B is a top view showing a state of the surface of the circuit board 9. The cross-sectional view in FIG. 7A shows a cross-section taken along: the line K-K in FIG. 7B. This board 9 is an example of a case in which for setting a high-density wiring, it is necessary to lay conductors around the region located directly below the heat sink plate 2.

Electrodes 10 formed on the board 9 are connected to electric signal terminals 5 of the semiconductor device 8 by a soldering material 11. Numeral 12 denotes a conductor formed at the central portion on the board 9 that is below the lower surface of the semiconductor device 8. The conductor 12 is formed to extend from an electrode 10a on the board 9 corresponding to one of the electric signal terminals 5 of the semiconductor device 8 to a via hole 13 formed in the board 9. The conductor 12 is connected through the via hole 13 to a conductor in an internal layer 14 in the board 9.

In this state, the conductor 12 on the board 9 and the exposed supporting portion 2b on the heat sink plate 2 of the semiconductor device 8 form opposing metal portions. In this state, when a soldering material 11a for the electric signal terminals 5 in the vicinity bulges out or excessive soldering material is separated and becomes a solder ball 15, and such a material is positioned between the conductor 12 and the heat sink plate 2, a short circuit occurs and the circuit characteristics become defective.

This board design is common in forming high-density electronic circuits in recent years, but forming board wiring directly below an exposed heat sink plate may cause a contact between the heat sink plate and the board wiring directly below it, so that such configuration is avoided as a risky design.

### SUMMARY OF THE INVENTION

It is an object of the present invention to provide a semiconductor device solving the above-described problems of the semiconductor device with a configuration in which a heat sink plate is exposed, so that it is possible to secure a degree of freedom in board wiring below the heat sink plate.

A semiconductor device with a first aspect of the invention includes a semiconductor chip; a heat sink plate on an upper surface of which the semiconductor chip is mounted and on a lower surface of which a plurality of heat releasing terminals are provided; a plurality of electric signal terminals that are regularly disposed in a lattice-like manner around the heat sink plate; a connection member that electrically connects the semiconductor chip and the electric signal terminals; and a sealing resin sealing the semiconductor chip, the heat sink plate, the electric signal terminals, and the connection member such that lower end surfaces of the electric signal terminals and the heat releasing terminals are exposed. The heat sink plate is formed as an integrated body including a protruding portion that protrudes from a central portion of an upper surface and supports the semiconductor chip, a plurality of supporting portions that are positioned around a rear surface of the protruding portion so as to support the protruding portion and that are exposed at a rear surface of the sealing resin, the plurality of heat releasing terminals, and a thin-walled portion that is recessed from lower end surfaces of the supporting portions and the heat releasing terminals. Lower surfaces of the protruding portion and the thin-walled portion are covered with the sealing resin. The plurality of supporting portions are disposed so that they are continuous with the protruding portion and symmetrical with each other around the protruding portion.

A semiconductor device with a second aspect of the invention has a basic configuration that is similar to that of the first aspect. The heat sink plate is provided with a flat upper surface that supports the semiconductor chip. A lower surface of the heat sink plate includes a plurality of heat releasing terminals having the same shape and arrangement as those of the electric signal terminals and exposed at a rear surface of the sealing resin, and a thin-walled portion, which corresponds to a region other than the heat releasing terminals, and which is recessed from a lower end surface of the heat releasing terminals. A lower surface of the thin-walled portion is covered with the sealing resin.

### BRIEF DESCRIPTION OF THE DRAWINGS

FIG. 1A and FIG. 1B are cross-sectional views showing a semiconductor device according to Embodiment 1. FIG. 1C is a bottom view thereof. FIG. 1D is a bottom view of a heat sink plate constituting the semiconductor device, and FIG. 1E is a bottom view of a lead frame constituting the same.

FIG. 2A and FIG. 2B are cross-sectional views showing a semiconductor device according to Embodiment 2. FIG. 2C is a bottom view thereof. FIG. 2D is a bottom view of a heat sink plate constituting the semiconductor device.

FIG. 3Aa is a cross-sectional view showing a semiconductor device according to Embodiment 3. FIG. 3Ab is a bottom view thereof. FIG. 3Ac is a bottom view of a heat sink plate constituting the semiconductor device.

FIG. 3Ba is a cross-sectional view showing an improved example of the semiconductor device according to Embodiment 3. FIG. 3Bb is a bottom view thereof FIG. 3Bc is a bottom view of a heat sink plate constituting the semiconductor device.

FIG. 4A is a cross-sectional view showing a semiconductor device according to Embodiment 4. FIG. 4B is a bottom view thereof. FIG. 4C is a bottom view of a heat sink plate constituting the semiconductor device.

FIG. 5Aa is a cross-sectional view showing a semiconductor device according to Embodiment 5. FIG. 5Ab is a bottom view thereof. FIG. 5Ac is a bottom view of a heat sink plate constituting the semiconductor device.

FIG. 5Ba is a cross-sectional view showing an improved example of the semiconductor device according to Embodiment 5. FIG. 5Bb is a bottom view thereof FIG. 5Bc is a bottom view of a heat sink plate constituting the semiconductor device.

FIG. 5C is a cross-sectional view showing a state in which the semiconductor device shown in FIG. 5Ba is mounted on a board.

FIG. 5Da and FIG. 5Db are cross-sectional views showing a state in which a heat sink plate is deformed when mounting a semiconductor chip for assembling a semiconductor device.

FIG. 6A is a cross-sectional view showing a semiconductor device according to a conventional example. FIG. 6B is a bottom view thereof. FIG. 6C is a bottom view of a heat sink plate constituting the semiconductor device, and FIG. 6D is a bottom view of a lead frame constituting the same.

FIG. 7A is a cross-sectional view showing a configuration in which the semiconductor device shown in FIG. 6A is mounted on a board, and FIG. 7B is a plan view of the pattern of the board surface.

### DESCRIPTION OF THE PREFERRED EMBODIMENTS

According to the semiconductor device with the configuration of the present invention, a substantial part on the lower surface of the heat sink plate that is conventionally exposed is embedded in a sealing resin, so that the surface area that is exposed at the lower surface of the heat sink plate from the sealing resin is reduced and a degree of freedom in board wiring below the heat sink plate can be improved.

In the above-mentioned configuration of a first aspect of the invention, an “integrated body” with respect to the heat sink plate means that the included elements are linked mutually so as to form one body. Further, “continuous with the protruding portion” with regard to the plurality of supporting portions means that the supporting portion and the protruding portion have a portion connected with each other.

In a semiconductor device according to the first aspect of the invention, it is preferable that a gap between the supporting portion and the heat releasing terminal and a gap between the supporting portions are at least as wide as a gap between neighboring electric signal terminals, and the heat releasing terminals are provided with a substantially identical shape and arrangement as those of the electric signal terminals.

Furthermore, the heat releasing terminals preferably are disposed symmetrically only at an outer peripheral portion of the heat sink plate. The supporting portions continuous with the protruding portion are preferably at least half as wide as the thickness of the electric signal terminals, and the supporting portions are preferably at least as long as the thickness of the electric signal terminals. A through hole preferably is formed in a part of the thin-walled portion of the heat sink plate. Preferably at least a part of the through hole is open to the upper side of the heat sink plate.

In a semiconductor device according to a second aspect of the invention, the heat releasing terminals can be disposed only at an outer peripheral portion of the heat sink plate. It is possible to dispose the heat releasing terminals at an outer peripheral portion and the central portion of the heat sink plate. A through hole is preferably formed in a part of the thin-walled portion of the heat sink plate.

Hereinafter, embodiments of a semiconductor device according to the present invention will be described with reference to the accompanying drawings.

### Embodiment 1

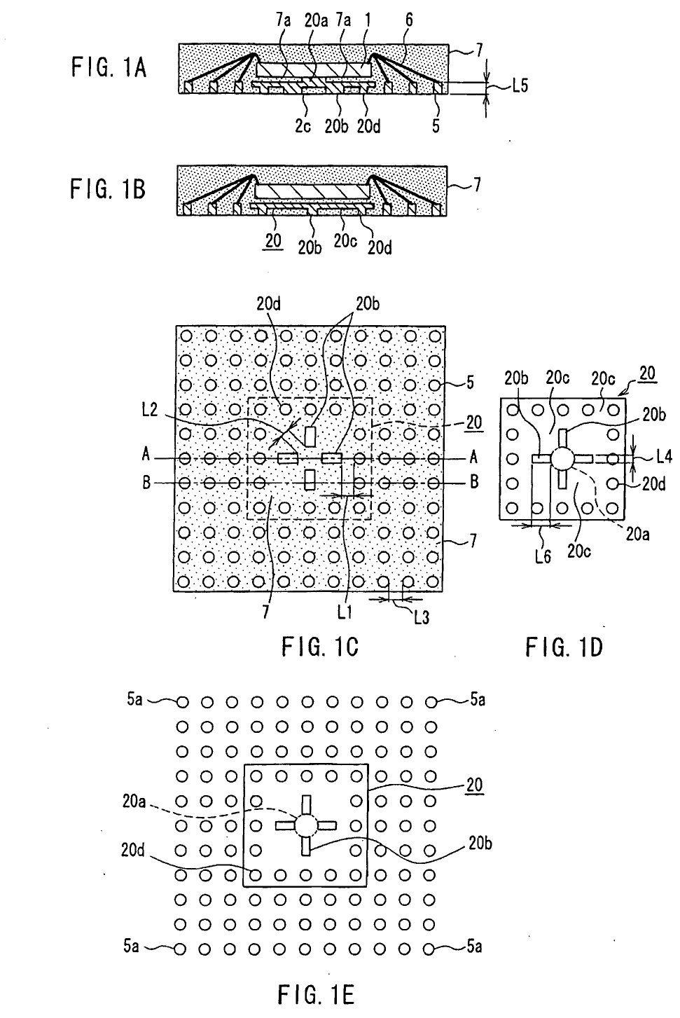

FIG. 1A to FIG. 1E show a configuration of a semiconductor device according to Embodiment 1 of the present invention. FIG. 1A and FIG. 1B are cross-sectional views, and FIG. 1C is a bottom view. FIG. 1A shows a cross-section taken along the line A-A, and FIG. 1B shows a cross-section taken along the line B-B in FIG. 1C. FIG. 1D is a bottom view of a heat sink plate 20 constituting the semiconductor device, and FIG. 1E is a bottom view of a configuration of a lead frame constituting the semiconductor device.

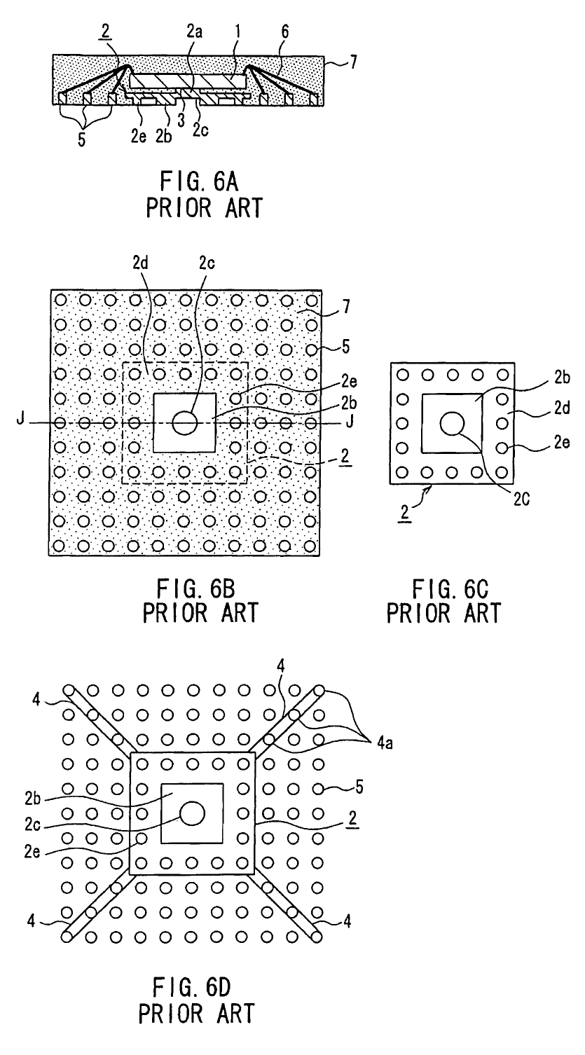

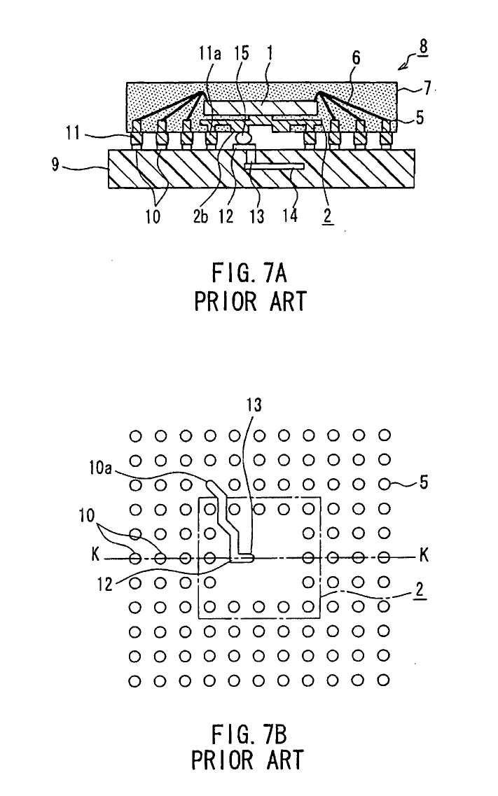

In the configuration of this semiconductor device, the configuration of the heat sink plate 20 is different from that of the heat sink plate 2 in the conventional example shown in FIG. 6A to FIG. 6D. Configurations of other parts are the same as those in the conventional example shown in FIG. 6A to FIG. 6D. To facilitate understanding, identical elements are denoted by identical numerals.

As in the conventional example, the upper surface of the heat sink plate 20 is provided with a protruding portion 20a on which a semiconductor chip 1 is mounted. The lower surface of the heat sink plate 20 is provided with supporting portions 20b at positions around the protruding portion 20a. The supporting portions 20b are full metal portions exposed at the lower surface of the sealing resin 7, and serve the purpose of holding the protruding portion 20a.

Furthermore, a thin-walled half-etched portion 20c and heat releasing terminals 20d are formed in the lower surface of the heat sink plate 20. The heat releasing terminals 20d, which are full metal portions that are provided with the same shape, size, and arrangement as those of electric signal terminals 5 around them, are exposed from the sealing resin 7 and are connected by solder to a circuit board to secure heat releasing. An advantage gained when the heat releasing terminals 20d have the same shape, size, and arrangement as the electric signal terminals 5 is that the pattern with which a soldering material is supplied when mounting on the board can be unified, which makes it easier to set the mounting parameters. It should be noted that when using solder balls as a material for connection to the board, the balls can have the same size as those used for the electric signal terminals 5. In order to simplify the land design, it is preferable to dispose the heat releasing terminals 20d so that they are arranged in sequence with the electric signal terminals 5. For example, the heat releasing terminals 20d may be disposed only at the outer peripheral portion of the heat sink plate 20, as shown in FIG. 1E.

Due to such a configuration of the supporting portions 20b of the heat sink plate 20, the half-etched portion 20c around the supporting portions 20b is covered with the sealing resin 7, so that it becomes possible to place conductors on the board surface corresponding to this portion. Different from one large rectangle as the supporting portion 2b in the conventional example shown in FIG. 6A to FIG. 6D, the supporting portions 20b according to this embodiment form four smaller rectangular shapes so that the supporting portions 20b are disposed along lines that intersect at right angle to one another. Therefore, the surface area that is exposed from the sealing resin 7 is reduced, which is advantageous for preventing short circuit by solder and making the wiring design of the board simple and regular.

A gap L1 between the supporting portions 20b and the heat releasing terminals 20d and a gap L2 between the supporting portions 20b are preferably at least as wide as a gap L3 between the electric signal terminals 5. Thus, short circuits can be prevented and it becomes possible to secure a sufficient degree of freedom in designing the wiring on the board. The supporting portions 20b have preferably a width IA that is at least half as wide as a thickness L5 of the lead frame (see FIG. 1A) and a length L6 that is at least as long as the width of the lead frame in order to secure a force for holding the protruding portion 20a.

As described above, this embodiment reduces an exposed area on the lower surface of the heat sink plate 20 in order to prevent, to the extent possible, the exposed portion of the heat sink plate 20 from being opposed to the conductors on the board. That is to say, a portion of the heat sink plate 20 that is conventionally exposed is replaced with a resin surface and is designed so that the conductors on the board can be disposed below it. Therefore, even when a foreign material is put on the conductors, problems such as a short circuit do not occur since the opposed surface on the side of the semiconductor device is a resin surface. It is preferable to enlarge, to the extent possible, the surface area of the region that is covered with resin below the heat sink plate 20, in order to secure a degree of freedom in board wiring on the board.

### Embodiment 2

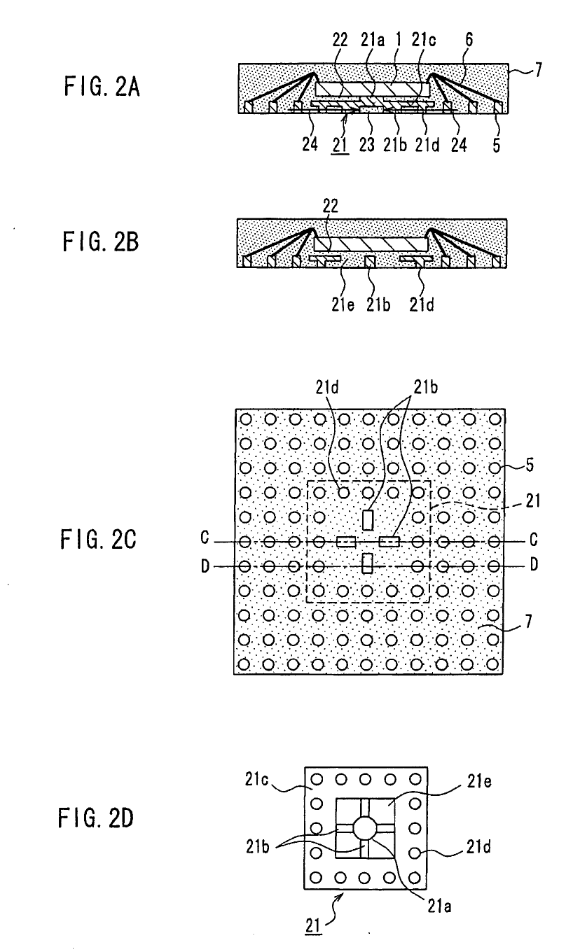

A semiconductor device according to Embodiment 2 shown in FIG. 2A to FIG. 2D has a heat sink plate that is configured to improve the efficiency of burying the lower surface of the heat sink plate 20 with the sealing resin 7 in the semiconductor device shown in FIG. 1A to FIG. 1E. FIG. 2A and FIG. 2B are cross-sectional views, and FIG. 2C is a bottom view. FIG. 2A shows a cross-section taken along the line C-C, and FIG. 2B shows a cross-section taken along the line D-D in FIG. 2C. FIG. 2D is a bottom view of a heat sink plate 21 constituting the semiconductor device.

In FIG. 1A and FIG. 1B, the lower surface of the heat sink plate 20 that is to be embedded in the sealing resin 7 is formed by half etching. However, since the gaps through which the sealing resin 7 flows are narrow, the filing state of the sealing resin 7 is poor, so that an unfilled portion may appear and a defect in external appearance may occur. Thus, it is desirable to facilitate the flow of the sealing resin 7 to the lower surface of the heat sink plate 20.

The configuration of the heat sink plate 21 of the semiconductor device shown in FIG. 2A to FIG. 2D solves this problem. The heat sink plate 21 is provided with a protruding portion 21a, supporting portions 21b, a half-etched portion 21c, and heat releasing terminals 21d, like the configuration in FIG. 1A to FIG. 1E. Furthermore, through holes 21e are formed in the heat sink plate 21. The through holes 21e are formed in advance by etching in a step of manufacturing the lead frame.

In the sealing step in the production of the semiconductor device, the sealing resin 7 flows from a gap 22 directly below the semiconductor chip 1 through the through holes 21e to a lower surface 23 of the heat sink plate 21. In the case without the through holes 21e, in FIG. 2A, for example, the route through which resin flows is the route indicated by an arrow 24, that is, only the route that extends through a narrow portion below the lower surface of the half-etched portion 21c in the lateral direction, so that the flow of the resin is poor and an unfilled portion may appear. On the other hand, if the through holes 21e are provided, as shown in FIG. 2A to FIG. 2D, the sealing resin 7 flows downward from the top through not only the portion below the lower surface of the half-etched portion 21c but also the through holes 21e, so that the efficiency of sealing the lower surface 23 of the heat sink plate 21 with resin is improved. When comparing the difference in the external appearance after the sealing with resin, using thirty semiconductor devices with and without the through holes 21e each, filling defects occurred in five cases without the through holes 21e, but there were no filling defects in the semiconductor devices with the through holes 21e.

It should be noted that the through holes 21e are formed so that they are continuous with the protruding portion 21a, as shown in FIG. 2D, so that the flow of the resin to below the protruding portion 21a is facilitated.

### Embodiment 3

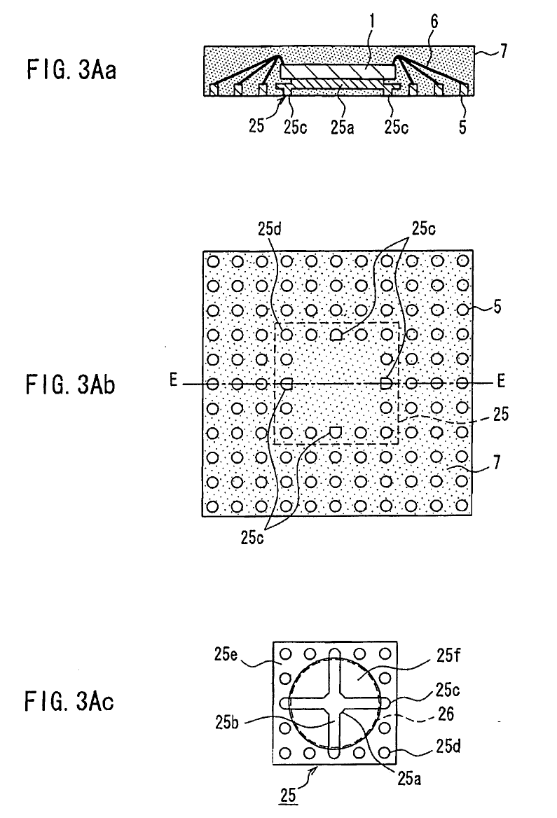

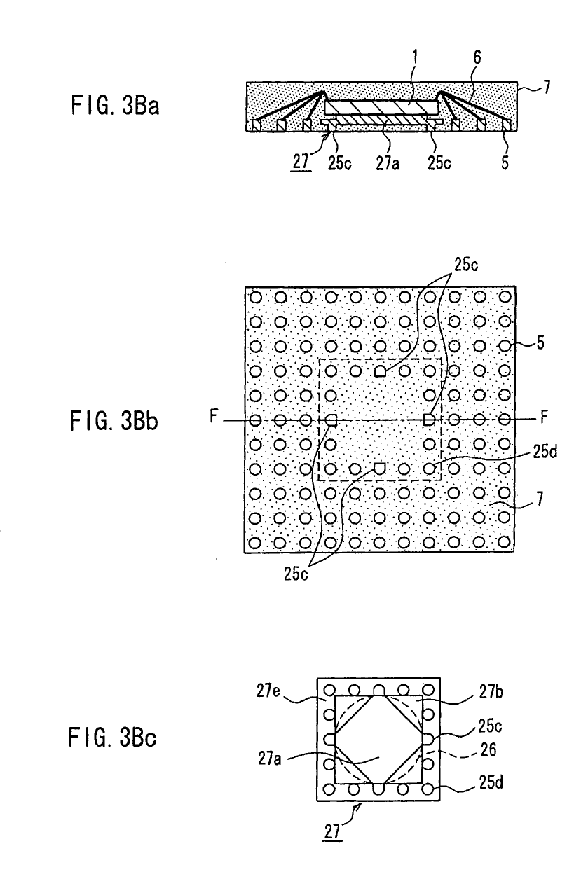

FIG. 3Aa to FIG. 3Ac show a semiconductor device according to Embodiment 3. FIG. 3Aa is a cross-sectional view, and FIG. 3Ab is a bottom view. FIG. 3Aa shows a cross-section taken along the line E-E in FIG. 3Ab. FIG. 3Ac is a bottom view of a heat sink plate 25 constituting the semiconductor device.

Unlike the four supporting portions 20b and 21b with the full metal exposure that hold the protruding portions 20a and 21a, which are shown in FIG. 1A and FIG. 2A, in this embodiment, supporting portions 25c are provided with a substantially similar shape and arrangement as the other exposed terminals, namely heat releasing terminals 25d and electric signal terminals 5, as shown in FIG. 3Ab.

As shown in FIG. 3Ac, the upper surface of the heat sink plate 25 is provided with a round protruding portion 25a on whose central portion the chip is mounted and auxiliary protruding portions 25b that extend from the protruding portion in form of a cross. The supporting portions 25c are formed on the front end portions of the auxiliary protruding portions 25b, and their shape is similar to that of the other terminals. The protruding portion 25a whose central portion is circular and the auxiliary protruding portions 25b in form of a cross are formed by cutting to the half the plate thickness with a press mold at an outline shape 26 indicated by the broken line, and the supporting portions 25c that support the auxiliary protruding portions have a shape such as a pistol bullet that is substantially similar to that of the heat releasing terminals 25d, as shown in FIG. 3Ab. As a result, it becomes possible to secure an even higher degree of freedom in board wiring. Furthermore, the supporting portions 25c can be connected by solder to the board for radiating heat. Numeral 25e denotes a half-etched portion, and numeral 25f denotes a through hole.

Next, an example in which the configuration in FIG. 3Aa to FIG. 3Ac is modified is shown in FIG. 3Ba to FIG. 3Bc. The auxiliary protruding portions 25b have a shape of a cross in the configuration in FIG. 3Aa to FIG. 3Ac, and since their width is narrow, the overall strength of the auxiliary protruding portions 25b is weak and there is a possibility of deformation when a chip is mounted thereon. For example for solving this, it is possible to use a shape of a heat sink plate 27 shown in FIG. 3Ba to FIG. 3Bc. A protruding portion 27a in this configuration is square. Triangular through holes 27b are formed in the configuration in FIG. 3Ba to FIG. 3Bc, corresponding to the through holes 25f in the configuration in FIG. 3Aa to FIG. 3Ac. Numeral 27e denotes a half-etched portion. Other portions are denoted by identical numerals as those in FIG. 3Aa to FIG. 3Ac, and further descriptions thereof are omitted. When the shape of the protruding portion 27a is changed from a cross to a square, the problem of the narrow width of the auxiliary protruding portions 25b in FIG. 3Aa to FIG. 3Ac is solved, and the strength of the protruding portion is increased. When the shape of the through holes 27b is triangular, the flow of the resin is as good as that in FIG. 3Aa to FIG. 3Ac and it is possible to secure a stable productivity and yield.

### Embodiment 4

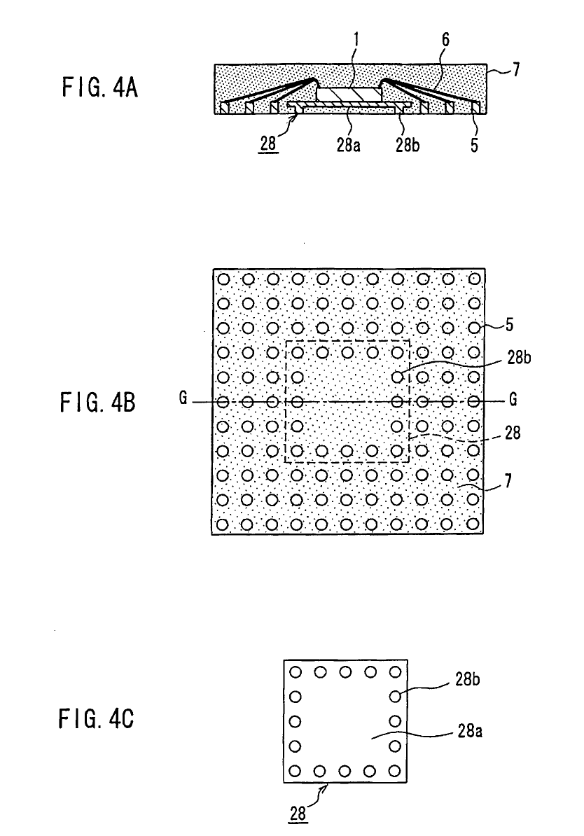

FIG. 4A is a cross-sectional view showing a semiconductor device according to Embodiment 4, and FIG. 4B is a bottom view of the same. FIG. 4A shows a cross-section taken along the line G-G in FIG. 4B. FIG. 4C is a bottom view of a heat sink plate 28 constituting the semiconductor device.

In this embodiment, the heat sink plate 28 has a flat configuration without a protruding portion at the central portion thereof. The semiconductor chip 1 is bonded by Ag paste on the central portion of the heat sink plate 28 whose upper surface is flat. In this case, it is not necessary to form a protruding portion or a supporting portion that holds the protruding portion, unlike in the embodiments described above. As a result, the external appearance of the exposed portion of the heat sink plate 28 on the lower surface of the semiconductor device is such that only heat releasing terminals 28b are disposed on a half-etched portion 28a, as shown in FIG. 4C. Since the exposed metal portions can be reduced to the extent possible, it is possible to secure a higher degree of freedom in board wiring.

### Embodiment 5

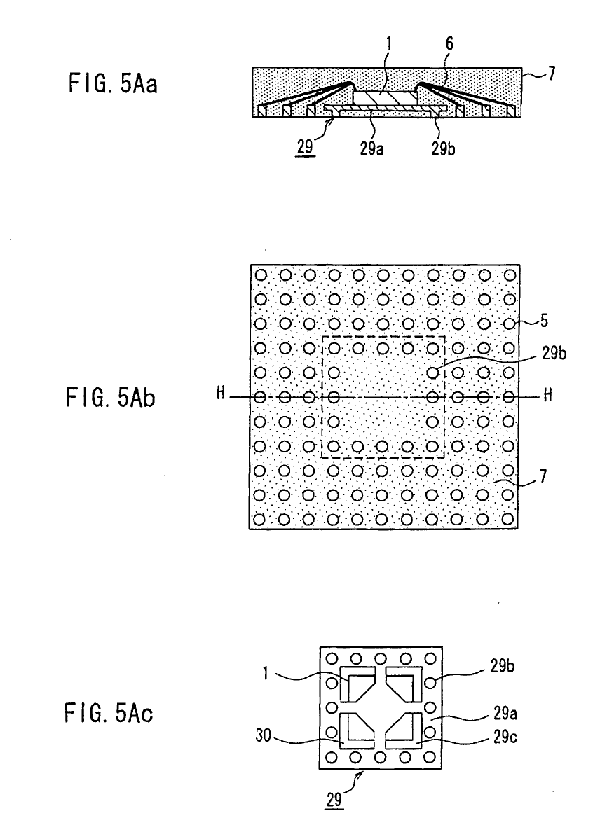

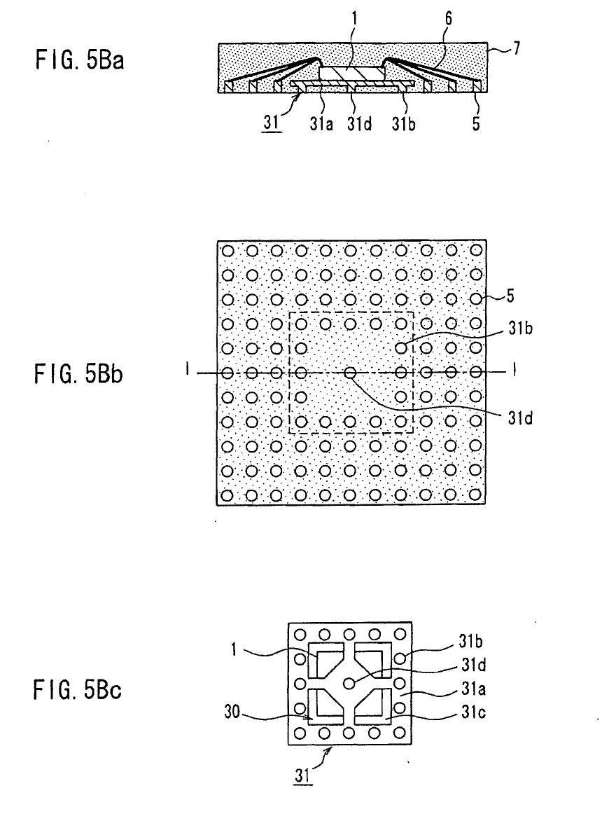

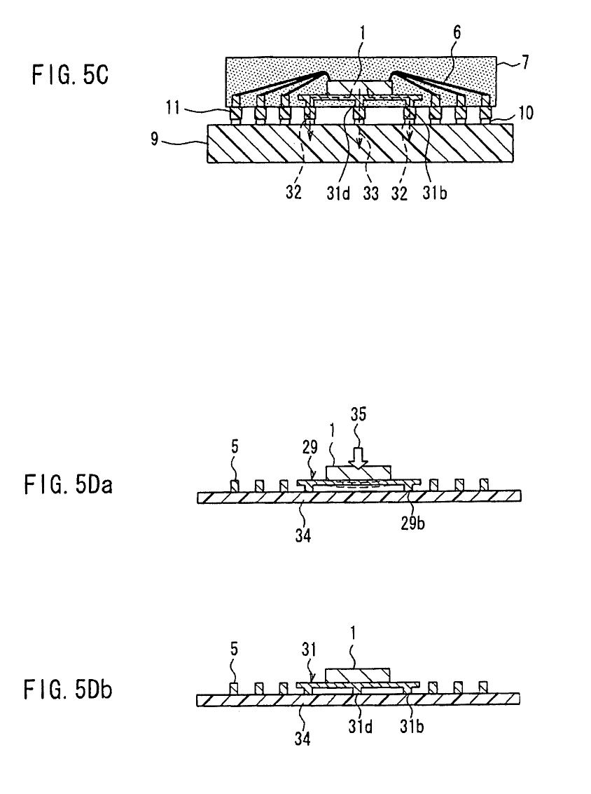

FIG. 5Aa is a cross-sectional view showing a semiconductor device according to Embodiment 5, and FIG. 5Ab is a bottom view of the same. FIG. 5Aa shows a cross section taken along the line H-H in FIG. 5Ab. FIG. 5Ac is a bottom view of a heat sink plate 29 constituting the semiconductor device. It should be noted that the semiconductor chip 1 is also shown in FIG. 5Ac. This embodiment is an improved example of Embodiment 4 shown in FIG. 4A to FIG. 4C.

In this embodiment, the upper surface of the heat sink plate 29 is flat like that in FIG. 4A to FIG. 4C and through holes 29c are provided on the inner side of heat releasing terminals 29b in a half-etched portion 29a, as shown in FIG. 5Ac. Therefore, a resin path 30 through which resin flows from the upper side to the lower side through the through holes 29c is formed. As a result, the flow of resin to the lower surface of the heat sink plate 29 is facilitated and the occurrence of defects in external appearance due to filling defects is reduced. It should be noted that it is necessary to set the outer size of the through holes 29c larger than the outer outline of the semiconductor chip 1 in order to enable the flow of the resin through the through holes 29c.

As described above, by providing the a heat sink plate with a flat upper surface without a protruding portion, and providing it with a through hole, it is possible to secure a degree of freedom in wiring on a circuit board, to facilitate the flow of resin to the lower surface of a heat sink plate, and to omit the step of processing the protruding portion.

FIG. 5Ba to FIG. 5Bc show an improved example of the configuration shown in FIG. 5Aa to FIG. 5Ac. FIG. 5Ba is a cross-sectional view, and FIG. 5Bb is a bottom view. FIG. 5Ba shows a cross-section taken along the line I-I in FIG. 5Bb. FIG. 5Bc is a bottom view of a heat sink plate 31 constituting the semiconductor device. FIG. 5C shows a cross-section of a state in which the semiconductor device shown in FIG. 5Ba is mounted on a board.

In this example, the central portion of the heat sink plate 31 is provided with a central heat releasing terminal 31d. The central heat releasing terminal 31d is an exposed full metal portion and has the same shape and size as those of electric signal terminals 5 or other heat releasing terminals 31b. Numeral 31a denotes a half-etched portion, and numeral 31c denotes a through hole.

When this semiconductor device is mounted on a board 9, the central heat releasing terminal 31d also is connected by solder at the same time, as shown in FIG. 5C. Thus, the heat that is generated during circuit operation in the semiconductor chip 1 is diffused and radiated to the board 9 through a heat releasing route 33 via the central heat releasing terminal 31d, as well as through a heat releasing route 32 via the heat releasing terminals 31b to the board 9. Therefore, the heat releasing efficiency is improved, and the value of a heat resistance, which is indicative of the heat releasing efficiency is improved by 10% to 30%.

Another effect that is gained when the central heat releasing terminal 31d is provided is shown in FIG. 5Da and FIG. 5Db. FIG. 5Da and FIG. 5Db show a state when the semiconductor chip 1 is mounted on the lead frame in the assembling step of the semiconductor device. FIG. 5Da shows a case with the heat sink plate 29 shown in FIG. 5Aa, and FIG. 5Db shows a case with the heat sink plate 31 including the central heat releasing terminal 31d shown in FIG. 5Ba.

As shown in FIG. 5Da, when starting to assemble the lead frame, the heat sink plate 29 and leads forming for example the electric signal terminals 5 are fixed on a sheet 34, and the semiconductor chip 1 is mounted thereon by applying a load in the direction indicated by an arrow 35, that is, downward from the top. At that time, the problem may occur that the heat sink plate 29 without the central heat releasing terminal 31d is deformed as indicated by the broken line. When the heat sink plate 29 is deformed, a defective external appearance or problems with regard to reliability of the semiconductor device may occur. Thus, it is necessary to mount the semiconductor ship 1 within a load range that does not cause deformations, so that the range of chip mounting conditions will be narrowed. On the other hand, when the central heat releasing terminal 31d is formed, the central heat releasing terminal 31d serves to support the load applied to the heat sink plate 31, so that the above-described deformations do not occur, as shown in FIG. 5Db.

As described above, the configuration shown in FIG. 5Ba to FIG. 5Bc has the two advantages of improving the heat releasing efficiency and of preventing the heat sink plate from being deformed during assembly.

The invention may be embodied in other forms without departing from the spirit or essential characteristics thereof. The embodiment disclosed in this application is to be considered in all respects as illustrative and not limiting. The scope of the invention is indicated by the appended claims rather than by the foregoing description, and all changes which come within the meaning and range of equivalency of the claims are intended to be embraced therein.

1. A semiconductor device, comprising:
a semiconductor chip;
a heat sink plate on an upper surface of which the semiconductor chip is mounted and on a lower surface of which a plurality of heat releasing terminals are provided;
a plurality of electric signal terminals that are regularly disposed in a lattice-like manner around the heat sink plate;
a connection member that electrically connects the semiconductor chip and the electric signal terminals; and
a sealing resin sealing the semiconductor chip, the heat sink plate, the electric signal terminals, and the connection member such that lower end surfaces of the electric signal terminals and the heat releasing terminals are exposed;
wherein the heat sink plate is formed as an integrated body including
a protruding portion that protrudes from a central portion of an upper surface and supports the semiconductor chip,
a plurality of supporting portions that are positioned around a rear surface of the protruding portion so as to support the protruding portion and that are exposed at a rear surface of the sealing resin,
the plurality of heat releasing terminals provided around and separate from the supporting portions, and
a thin-walled portion that is recessed from lower end surfaces of the supporting portions and the heat releasing terminals;
wherein a through hole is formed in a part of the thin-walled portion of the heat sink plate; and
lower surfaces of the protruding portion and the thin-walled portion are covered with the sealing resin; and
wherein the plurality of supporting portions are disposed so that they are continuous with the protruding portion and symmetrical to each other around the protruding portion.

2. The semiconductor device according to claim 1,
wherein a gap between the supporting portion and the heat releasing terminal is at least as wide as a gap between neighboring electric signal terminals, and the heat releasing terminals are provided with a substantially identical shape and arrangement relative to those of the electric signal terminals.

3. The semiconductor device according to claim 1,
wherein the heat releasing terminals are disposed symmetrically only at an outer peripheral portion of the heat sink plate.

4. The semiconductor device according to claim 1,
wherein the supporting portions continuous with the protruding portion have a width at least half as wide as the thickness of the electric signal terminals, and the supporting portions are at least as long as the thickness of the electric signal terminals.

5. (canceled)

6. The semiconductor device according to claim 1,
wherein at least a part of the through hole is open to the upper side of the heat sink plate.

7. A semiconductor device, comprising:
a semiconductor chip;
a heat sink plate on an upper surface of which the semiconductor chip is mounted and on a lower surface of which a plurality of heat releasing terminals are provided;
a plurality of electric signal terminals that are regularly disposed in a lattice-like manner around the heat sink plate;
a connection member that electrically connects the semiconductor chip and the electric signal terminals; and
a sealing resin sealing the semiconductor chip, the heat sink plate, the electric signal terminals, and the connection member such that lower end surfaces of the electric signal terminals and the heat releasing terminals are exposed;
wherein the heat sink plate is provided with a flat upper surface that supports the semiconductor chip,
wherein a lower surface of the heat sink plate includes a plurality of heat releasing terminals having the same shape and arrangement as those of the electric signal terminals and exposed at a rear surface of the sealing resin, and a thin-walled portion, which corresponds to a region other than the heat releasing terminals and is recessed from a lower end surface of the heat releasing terminals, and
wherein a lower surface of the thin-walled portion is covered with the sealing resin.

8. The semiconductor device according to claim 7,
wherein the heat releasing terminals are disposed only at an outer peripheral portion of the heat sink plate.

9. The semiconductor device according to claim 7,
wherein the heat releasing terminals are disposed at an outer peripheral portion and a central portion of the heat sink plate.

10. The semiconductor device according to claim 7,
wherein a through hole is formed in a part of the thin-walled portion of the heat sink plate.

11. The semiconductor device according to claim 1,
wherein any neighboring pairs of the supporting portions are separated by a gap that is at least as wide as a gap between neighboring pairs of electric signal terminals.
